(19) United States
(12) Patent Application Publication
(10) Pub. No.: US 2011/0204518 A1
(43) Pub. Date: Aug. 25, 2011

(54) SCALABILITY WITH REDUCED CONTACT RESISTANCE

(75) Inventor: Valli Arunachalam, Pleasant Valley, NY (US)

(73) Assignee: GLOBALFOUNDRIES Inc., Grand Cayman (KY)

(21) Appl. No.: 12/711,005

(22) Filed: Feb. 23, 2010

(51) Int. Cl. H01L 23/48; H01L 21/768

(52) U.S. Cl. 257/751; 438/653; 438/658; 257/E23.011; 257/E21.584; 257/E21.582

(57) ABSTRACT

Miniaturized semiconductor devices are formed with improved liner/barrier layer properties and, hence, improved contact resistance. Embodiments include semiconductor devices comprising contacts and vias with annealed liner/barrier layers having decreased carbon content and increased density. An embodiment includes depositing a metal containing layer, such as at least one member selected from the group consisting of titanium (Ti), tantalum (Ta), titanium nitride (TiN), tantalum nitride (TaN), tungsten nitride (WN), cobalt (Co), and ruthenium (Ru) to line an opening formed in a dielectric layer, and annealing the deposited metal containing layer, as in a non-oxidizing atmosphere, to increase its density, decrease defects, and alter its material composition, for example, reduce its carbon content. As a result, a metal, e.g., W or Cu, plug filing the contact/via exhibits a reduced surface roughness and defectivity, and thereby improved contact resistance and reliability.

### TECHNICAL FIELD

The present disclosure relates to miniaturized semiconductor devices with improved contact resistance and reliability. The present disclosure is particularly applicable to miniaturized semiconductor devices with improved liner/barrier layer properties.

### BACKGROUND

Conductive contacts and vias are formed to electrically connect source/drain regions and conductive features of an integrated circuit. The contacts/vias are conventionally formed by patterning and etching a dielectric material layer to form an opening therein, depositing a liner/barrier layer, typically a combination of layers, such as of titanium (Ti), tantalum (Ta), ruthenium (Ru), titanium nitride (TiN), tantalum nitride (TaN), tungsten nitride (WN), and/or cobalt (Co), to line the side surfaces and bottom of the opening, and depositing a conductive plug, such as tungsten (W) or copper (Cu), to fill the opening. The liner/barrier prevents diffusion of conductive material into the dielectric material layer and enhances adhesion of the conductive plug to the walls of the contact opening.

As the dimensions of contacts/vias decrease, the amount of resistive barrier material, e.g., TiN, inside the contact must be minimized to facilitate better filling and lower contact resistance. However, barrier thickness scaling required for reducing contact resistance is often accompanied by deterioration of barrier properties, i.e., the ability of the barrier to prevent fluorine attack of the underlying Ti during W or Cu deposition resulting in defects, unfilled contacts, increased contact resistance, and reduced device reliability.

Barrier layers are conventionally deposited by chemical vapor deposition (CVD) or atomic layer deposition (ALD) techniques using metal organic precursors, which results in residual carbon in the deposited layers. The ability of the deposited layer to block fluorine attack of the underlying Ti decreases with increasing carbon content of the deposited layer. Direct and remote plasma treatments in a nitrogen/hydrogen (N₂/H₂), N₂, or H₂ ambient have been employed to densify barrier layers.

Direct plasma treatments densify the barrier layers by volatilizing the carbon through direct ionic bombardment. However, due to the directional nature of the plasma, the barrier layer is typically thicker and less densified on the sidewalls as compared to the field area and the contact/via bottom. While increasing plasma power and/or time can further reduce carbon content in the field area and contact/via bottom, it cannot densify the film on the sidewall. This, in turn, leads to defects associated with fluorine attack, and degraded contact resistance and transistor performance. Remote plasma treatments densify the barrier layer isotropically by volatilizing carbon through chemical reactions with radicals created by the plasma. However, in both types of plasma treatments, some residual carbon remains in the barrier layer.

Fluorine attack of the underlying metal containing layer, e.g., Ti, that accompanies a barrier layer thickness reduction, can be mitigated somewhat by increasing the W nucleation thickness. However, the step coverage of W nucleation layers is worse than of bulk CVD W processes, and the resistivity is higher, leading to poor fill, with large seam voids, and high resistance, especially as feature sizes become smaller. Decreasing the temperature of the bulk CVD W fill portion of the process can also result in reduced fluorine attack of the underlying Ti. However, this adversely impacts W grain size and, consequently, contact resistance.

A need therefore exists for methodology enabling a reduction in barrier layer thickness of a contact or via without deteriorating its barrier properties or adversely affecting the contact resistance.

### SUMMARY

An aspect of the present disclosure is a semiconductor device comprising a metal containing layer with increased density and decreased carbon content.

Another aspect of the present disclosure is a method of fabricating a semiconductor device comprising a metal containing layer with increased density and decreased carbon content.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method of fabricating a semiconductor device, the method comprising: depositing a liner/barrier layer, for example, a metal containing layer; and annealing the deposited metal/barrier layer under conditions sufficient to increase the density and decrease the carbon content of the barrier layer.

Aspects of the present disclosure include the liner/barrier layer comprising at least one member selected from the group consisting of Ti, Ta, TiN, TaN, WN, Co, and Ru, for example, a first liner layer comprising Ti, and a second barrier layer thereon comprising TiN. The second barrier layer may alternatively comprise, for example, TaN, WN, Co, or Ru. Further aspects include forming a dielectric layer over a substrate; forming an opening in the dielectric layer; and depositing the liner/barrier layer to line the opening. Another aspect includes depositing the liner/barrierlayer to a thickness of about 5 Å to about 50 Å. Additional aspects include filling the opening by depositing W by CVD employing fluorine-containing tungsten precursors, or by depositing copper (Cu) by CVD employing fluorine-containing Cu precursors, subsequent to annealing. Further aspects include depositing the liner/barrierlayer by CVD or ALD. Another aspect includes annealing the liner/barrierlayer in a non-oxidizing gas atmosphere, e.g., an atmosphere comprising a noble gas, N₂, H₂, or a forming gas comprising N₂ and H₂. A further aspect includes annealing the liner/barrierlayer at a temperature of about 100° C. to about 500° C., e.g., at a temperature of about 100° C. to about 400° C. An additional aspect includes performing the deposition and annealing steps in a single chamber with no vacuum break after the deposition.

Another aspect of the present disclosure is a semiconductor device comprising: a dielectric layer; an opening formed in the dielectric layer; an annealed metal containing layer lining the opening; and a conductive material in contact with the annealed metal containing layer filling the opening.

Aspects include the metal containing layer comprising at least one member selected from the group consisting of Ti, TiN, TaN, WN, Co, and Ru. Another aspect includes the metal containing layer comprising a first layer comprising Ti, and a second layer thereon comprising TiN, TaN, WN, Co, or Ru. A further aspect includes the conductive material comprises W or Cu. An additional aspect includes the annealed metal containing layer having a thickness of about 5 Å to about 50 Å.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawing and in which like reference numerals refer to similar elements and in which:

FIG. 1 schematically illustrates structure of a conventional contact or via;

FIG. 2 is a flowchart of a method in accordance with an exemplary embodiment of the disclosure; and

FIG. 3 shows defect density with and without an annealing step prior to deposition of W.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments.

The present disclosure addresses and solves the problem of degradation of metal containing layer barrier properties in contacts/vias as the thickness of the metal containing layer decreases with increasing scalability. In accordance with embodiments of the present disclosure, the metal containing layer is annealed under conditions designed to remove residual carbon and increase its density, thereby decreasing defects and improving its barrier properties. Consequently, a conductive plug subsequently deposited on the metal containing layer to fill the opening exhibits decreased roughness and improved contact resistance.

Methodology in accordance with embodiments of the present disclosure includes depositing a metal containing layer and annealing the deposited metal containing layer under conditions sufficient to increase its density and decrease its carbon content. In this way the thickness of the metal containing layer may be reduced, such as to about 5 Å to about 50 Å, without degrading its barrier properties. The metal containing layer may be formed of Ti, TiN, TaN, WN, Co, and Ru, e.g., a composite comprising a first layer of Ti, and a second layer thereon of TiN, TaN, WN, Co, or Ru. To maintain the conductivity of the layer, the anneal may take place in a non-oxidizing gas atmosphere, such as a noble gas, nitrogen (N₂), hydrogen (H₂), or a forming gas comprising N₂ and H₂. A H₂ containing atmosphere advantageously results in a reaction between the H₂ and the residual carbon to form a hydrocarbon, thereby reducing the amount of residual carbon in the metal containing layer and, hence, improving its barrier properties. In an embodiment, a dielectric layer is formed over a substrate, an opening is formed in the dielectric layer in a conventional manner, and the metal containing layer is deposited, as by CVD or ALD, to line the opening. The opening is then filled by depositing W, as by CVD employing WF₆, or by depositing Cu by CVD employing fluorine-containing Cu precursors, subsequent to annealing. Embodiments include annealing at a temperature of about 100° C. to about 500° C., e.g., about 100° C. to about 400° C. By employing low temperature annealing, e.g., below about 400° C., other elements of the semiconductor device are not adversely affected. Other embodiments include conducting deposition and annealing in a single chamber or tool with no vacuum break after the deposition, thereby improving efficiency, reducing the rejection rate, and improving manufacturing throughput.

Still other aspects, features, and technical effects will be readily apparent to those skilled in this art from the following detailed description, wherein preferred embodiments are shown and described, simply by way of illustration of the best mode contemplated. The disclosure is capable of other and different embodiments, and its several details are capable of modifications in various obvious respects. Accordingly, the drawings and description are to be regarded as illustrative in nature, and not as restrictive.

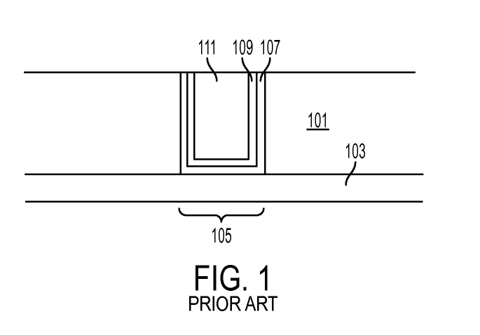

FIG. 1 illustrates the structure of a conventional contact. As shown, a dielectric layer 101 is formed on a substrate 103. An opening 105 is formed in dielectric layer 101, e.g., by photolithographic and etching techniques. A liner 107 and a barrier layer 109 are deposited to line the opening, and a conductive plug 111 is deposited on barrier layer 109 to fill the opening. Liner 107 may be formed of Ti, and barrier layer 109 may be formed of TiN, TaN, WN, Co, or Ru. The thickness of liner 107/barrier layer 109 is typically greater than about 15 Å, as barrier properties may be degraded for layers thinner than about 15 Å. For example, when filling the opening by depositing W by CVD employing WF₆, or by depositing Cu using a fluorine-containing Cu precursor, fluorine penetrates barrier layer 109 and attacks the underlying Ti, causing defects and, hence, increasing the surface roughness of the W or Cu plug, adversely increasing contact resistance and decreasing device reliability.

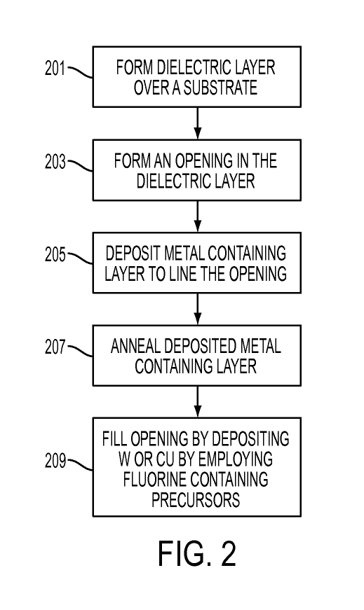

Adverting to FIG. 2, a flowchart illustrates a method in accordance with an exemplary embodiment of the disclosure. A dielectric layer, e.g., an interlayer dielectric (ILD), is deposited on a substrate in step 201. The dielectric layer may be formed on transistor source/drain regions, a transistor gate electrode, metal lines, or another conductive region on the substrate. In step 203, an opening is formed in the dielectric layer, as by photolithography and etching.

A metal containing layer is deposited to line the opening (step 205). This lining layer may be formed of Ti, TiN, TaN, WN, Co, or Ru, for example, by initially forming a first layer of Ti followed by a second layer of TiN. The metal lining layer is typically deposited to a thickness of about 5 Å to about 50 Å by CVD or ALD using metal organic precursors, and may be treated by an in situ plasma to reduce carbon content.

In step 207, the metal containing layer is annealed under conditions sufficient to modify its density, and alter its material composition, for example, further reduce its residual carbon content. Annealing may be conducted in a non-oxidizing atmosphere, e.g., nitrogen (N₂), hydrogen (H₂), a forming gas of N₂ and H₂, or a noble gas, such as argon Annealing in a H₂-containing atmosphere causes a reaction of H₂ with the residual carbon to form hydrocarbon(s), thereby reducing the amount of residual carbon in the metal containing layer. The annealing temperature and duration are dependent on the device and the underlying materials, and may range from about 100° C. to about 500° C., for example about 100° C. to about 400° C. Annealing at temperatures below about 400° C. avoids degradation of both metal/high-K gate electrodes and silicide layers in the semiconductor device.

Advantageously, steps 205 and 207 are conducted in the same stand-alone tool with no break in the vacuum between the two steps. In this way, efficiency is improved, defects further minimized, and manufacturing throughput increased.

In step 209, the opening is filled, for example by depositing W by or Cu.

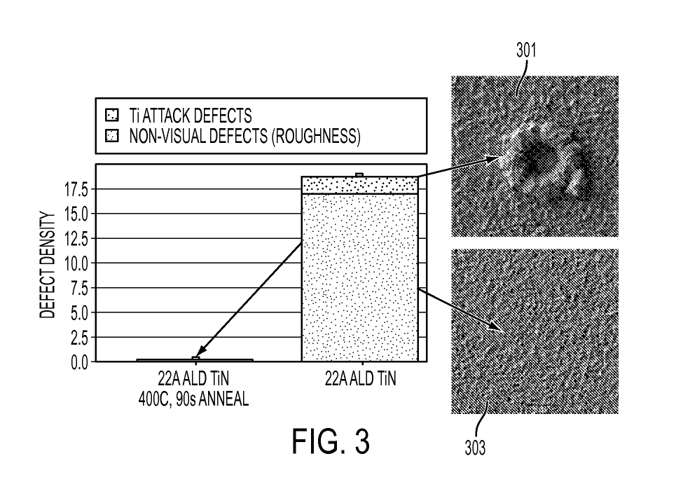

FIG. 3 shows the results of forming a W contact or via with a Ti/TiN liner/barrier layer both with and without an annealing step prior to W deposition. In each case, the TiN layer was deposited by ALD to a thickness of 22 Å. The W contact with the unannealed layer displayed a high density of defects, i.e., defects 301 caused by fluorine attacking the underlying Ti, and non-visual defects, or roughness, 303 of the W layer. On the other hand, as shown in FIG. 3, annealing the TiN layer for 90 seconds at 400° C. significantly reduced both types or defects. The benefits from annealing are not confined to thin metal containing layers but to thicker metal containing layers, e.g., metal containing layers having a thickness greater than 50 Å.

The embodiments of the present disclosure can achieve several technical effects, including improved contact resistance and reliability through improvement in the barrier properties of the liner, potential for improvement in W or Cu nucleation growth rate, uniformity, and reduced film roughness, and improved scalability and extendibility of currently used liner/barrier materials to smaller feature sizes through improvement of barrier properties. This translates to cost savings by postponing the introduction of newer liner materials and the associated process development and integration costs, while the annealing step is low cost and can be done in existing toolsets, such as degas chambers of liner tools and standalone RTP chambers. The present disclosure enjoys industrial applicability in any of various types of highly integrated semiconductor devices.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method of fabricating a semiconductor device, the method comprising:
depositing a metal containing layer; and
annealing the deposited metal containing layer under conditions sufficient to increase its density and decrease its carbon content or alter its material composition.

2. The method according to claim 1, wherein the metal containing layer comprises members selected from the group consisting of titanium (Ti), tantalum (Ta), titanium nitride (TiN), tantalum nitride (TaN), tungsten nitride (WN), cobalt (Co), and ruthenium (Ru).

3. The method according to claim 1, further comprising:
forming a dielectric layer over a substrate;
forming an opening in the dielectric layer; and
depositing the metal containing layer to line the opening.

4. The method according to claim 3, comprising depositing the metal containing layer to a thickness of about 5 Å to about 50 Å.

5. The method according to claim 3, wherein the metal containing layer comprises at least one members selected from the group consisting of Ti, Ta, TiN, TaN, WN, Co, and Ru.

6. The method according to claim 5, wherein the metal containing layer comprises a bilayer of a first layer and a second layer thereon.

7. The method according to claim 3, further comprising:
filling the opening by depositing tungsten (W) by chemical vapor deposition (CVD) employing fluorine-containing tungsten precursors, or by depositing copper (Cu) by CVD employing fluorine-containing Cu precursors, subsequent to annealing.

8. The method according to claim 3, comprising depositing the metal containing layer by CVD or atomic layer deposition (ALD).

9. The method according to claim 3, comprising annealing the metal containing layer in a non-oxidizing gas atmosphere.

10. The method according to claim 9, comprising annealing the metal containing layer in an atmosphere comprising a noble gas, nitrogen (N₂), hydrogen (H₂), or a forming gas comprising N₂ and H₂.

11. The method according to claim 3, comprising annealing the metal containing layer at a temperature of about 100° C. to about 500° C.

12. The method according to claim 11, comprising annealing the metal containing layer at a temperature of about 100° C. to about 400° C.

13. The method according to claim 2, comprising performing the deposition and annealing steps in a single chamber with no vacuum break after the deposition.

14. A semiconductor device comprising:
a dielectric layer;
an opening formed in the dielectric layer;
an annealed metal containing layer lining the opening; and
a conductive material in contact with the annealed metal containing layer filling the opening.

15. The semiconductor device according to claim 14, wherein the metal containing layer comprises a member selected from the group consisting of Ti, Ta, TiN, TaN, WN, Co, and Ru.

16. The semiconductor device according to claim 15, wherein the metal containing layer comprises a bilayer of a first layer and a second layer thereon.

17. The semiconductor device according to claim 14, wherein the conductive material comprises W or copper Cu.

18. The semiconductor device according to claim 14, wherein the annealed metal containing layer has a thickness of about 5 Å to about 50 Å.

19. A method of fabricating a semiconductor device, the method comprising:
forming a dielectric layer;
forming an opening in the dielectric layer;
depositing a metal lining in the opening;
annealing the deposited metal lining under conditions sufficient to decrease its carbon content and increase its density.

20. The method according to claim 19, comprising:
depositing the metal lining at a thickness of about 5 Å to about 50 Å; and
annealing the deposited metal lining at a temperature of about 100° C. to about 400° C. in a non-oxidizing atmosphere or a hydrogen containing atmosphere such that the hydrogen reacts with carbon in the deposited metal lining to form a hydrocarbon thereby reducing the amount of carbon in the metal lining.
